(19) United States
(12) Patent Application Publication
(10) Pub. No.: US 2023/0023612 A1
(43) Pub. Date: Jan. 26, 2023

(54) POWER PLUG

(71) Applicant: G-YOUTH TECHNOLOGIES (SHENZHEN) CO. LTD., Shenzhen City, Guangdong Province (CN)

(72) Inventors: Simon FENG, Shenzhen City (CN); Min FAN, Shenzhen City (CN); Li FAN, Shenzhen City (CN)

(73) Assignee: G-YOUTH TECHNOLOGIES (SHENZHEN) CO. LTD., Shenzhen City, Guangdong Province (CN)

(21) Appl. No.: 17/783,898

(22) PCT Filed: Dec. 10, 2019
(86) PCT No.: PCT/CN2019/124416

§ 371 Date: Jun. 9, 2022

(51) Int. Cl. H01R 31/06; H01R 12/70; H01R 12/71; H05K 5/00; H01R 13/02; H01R 13/73

(52) U.S. Cl. CPC H01R 31/06; H01R 12/7082; H01R 12/718; H05K 5/0069; H01R 13/02; H01R 13/73; H05K 5/0043

(57) ABSTRACT

A power plug includes a conductive module, a pin, an adapter terminal and a circuit board. The conductive module includes an injection-molded insulating body and a contact terminal secured to the insulating body during an injection molding process. The contact terminal includes a tail portion extending beyond the insulating body from one side of the insulating body and configured to be connected to the pin, and a contact portion extending beyond the insulating body from another side of the insulating body and configured to mate with the adapter terminal. The adapter terminal is electrically connected with the circuit board.

### TECHNICAL FIELD

The present disclosure relates to an electronic peripheral field of products such as mobile phones, in particular to a power plug.

### BACKGROUND

Power plugs are essential for electronic products such as mobile phones. Especially with the development of smart phones, the power consumption of the mobile phones is very fast and basically needs to be charged every day. For young consumers, it is necessary to carry a power plug with them when they go to work, on business trips, or traveling, in order to avoid the trouble of shutting down their mobile phones at any time when they are out of power. The existing power plug includes a housing and a pin which is hinged in the housing at one end and protruding beyond the housing at the other end and can be rotated around the hinged end to be retracted or unfolded. Corresponding to a top of the pin in the housing, there is an elastic piece which is in contact with the pin and conducts electricity when the pin is unfolded. The elastic piece includes a connecting arm for being fixed on the housing, and a first bent portion and a second bent portion formed by bending and extending in turn from one end of the connecting arm adjacent to the pin toward the pin. A side surface of the first bent portion facing the pin constitutes a contact surface which is in electrical contact with the pin. A hinge seat is arranged inside the housing. The pin is hinged on the hinge seat through a rotating shaft. The hinge seat includes a first fixing seat extending from a bottom wall of the housing toward an interior of the housing, and a second fixing seat disposed above the first fixing seat and matching with the first fixing seat. The second fixing seat is provided with a fixing portion corresponding to the connecting arm of the elastic piece. The elastic piece is fastened in the housing through the second fixing seat. Therefore, the shrapnel in the existing power plug is assembled to the housing, the assembly process is cumbersome, the structure is complicated, and the connection is unstable.

Therefore, it is necessary to provide a new power plug to solve the above problems.

### SUMMARY

An object of the present disclosure is to provide a power plug which has advantages of simple assembly and high safety etc.

To achieve the above object, the present disclosure adopts the following technical solutions: a power plug, including: a conductive module, a pin, an adapter terminal and a circuit board, the conductive module including an injection-molded insulating body and a contact terminal secured to the insulating body during an injection molding process, the contact terminal including a tail portion which extends beyond the insulating body from one side of the insulating body and is configured to be connected to the pin, and a contact portion which extends beyond the insulating body from another side of the insulating body and is configured to mate with the adapter terminal, the adapter terminal being electrically connected with the circuit board.

As a further improved technical solution of the present disclosure, the power plug further includes a housing which includes a bottom wall and a side wall, the bottom wall and the side wall are enclosed to form a receiving space, the side wall includes a buckle portion extending toward the receiving space, the insulating body is provided with a convex portion, the buckle portion mates with the convex portion to hold and position the insulating body on the housing.

As a further improved technical solution of the present disclosure, the contact portion includes a first contact arm, a second contact arm, and a connecting arm connected between the first contact arm and the second contact arm; the first contact arm, the connecting arm and the second contact arm form a U-shaped receiving cavity; the adapter terminal includes a base portion, a mating portion extending downwardly from the base portion, and a retaining portion extending downwardly from the base portion in a same direction as the mating portion; and the mating portion is inserted into the receiving cavity and is in constant contact with the contact portion.

As a further improved technical solution of the present disclosure, the mating portion includes a third contact arm which is bent and extended from the base portion, and a fourth contact arm which is reversely bent from an end of the third contact arm and is parallel to the third contact arm; the first contact arm and the third contact arm are mated; and the second contact arm and the fourth contact arm are mated.

As a further improved technical solution of the present disclosure, the circuit board is provided with a conductive hole, and the retaining portion is inserted into the conductive hole.

As a further improved technical solution of the present disclosure, the contact portion is located below the circuit board, and the base portion is located above the circuit board.

As a further improved technical solution of the present disclosure, the number of the contact terminals is two, the two contact terminals have two tail portions and two contact portions, the two tail portions are disposed side by side in a first plane, and the two contact portions are disposed side by side in a second plane which is orthogonal to the first plane.

As a further improved technical solution of the present disclosure, the power plug further includes a rotating shaft pivotally connecting the pin to the insulating body, the pin includes a first end and a second end which extend oppositely from the rotating shaft, the pin is rotatable around the rotating shaft so that the first end and the tail portion are detachably contacted.

As a further improved technical solution of the present disclosure, the side wall is provided with an opening communicating with the receiving space, the second end being capable of being embedded or protruded from the opening with rotation of the pin.

As a further improved technical solution of the present disclosure, an upper cover for closing the receiving space is installed above the housing, and a lower cover is attached and installed below the bottom wall of the housing.

Compared with the related art, the contact terminal and the insulating body of the power plug of the present disclosure are integrally formed into the terminal module, and then the terminal module is assembled into the housing. The present disclosure is convenient to assemble and replace, and is more stable in use, thereby having the advantages of low cost, high strength, high safety and simple assembly etc.

### BRIEF DESCRIPTION OF DRAWINGS

FIG. 1 is a perspective view of a power plug of the present disclosure;

FIG. 2 is a partial exploded view of the power plug of the present disclosure;

FIG. 3 is a further exploded view of FIG. 2;

FIG. 4 is a schematic view of FIG. 3 from another angle;

FIG. 5 is a perspective view of pins, a rotating shaft and an insulating body of the power plug of the present disclosure;

FIG. 6 is a perspective view of the pins and the rotating shaft of the power plug of the present disclosure;

FIG. 7 is a perspective view of contact terminals, adapter terminals and the insulating body of the power plug of the present disclosure;

FIG. 8 is an exploded perspective view of FIG. 7; and

FIG. 9 is a front view of the contact terminals, the adapter terminals, the insulating body and a circuit board of the power plug of the present disclosure after being assembled.

### DETAILED DESCRIPTION

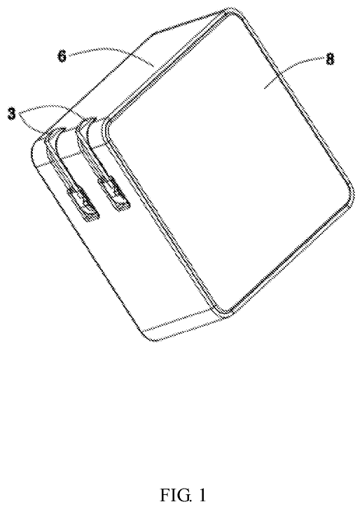

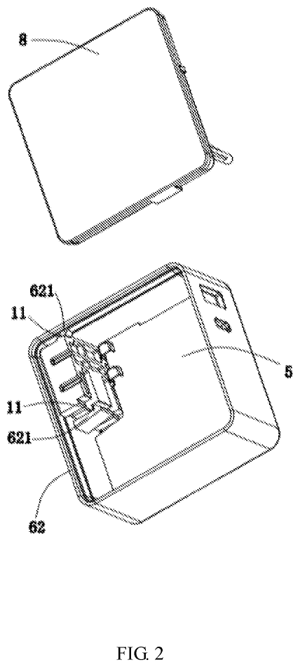

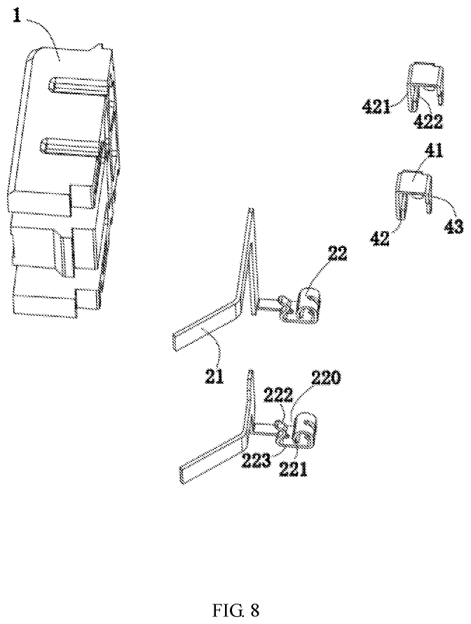

Referring to FIG. 1 to FIG. 9, a power plug includes a conductive module (not numbered), pins 3, adapter terminals 4 and a circuit board 5. The conductive module (not numbered) includes an injection-molded insulating body 1 and contact terminals 2 secured to the insulating body 1 during an injection molding process. The contact terminal 2 has a tail portion 21 which extends beyond the insulating body 1 from one side of the insulating body 1 and can be connected to the pin 3, and a contact portion 22 which extends beyond the insulating body 1 from the other side of the insulating body 1 and is mated with the adapter terminal 4. The adapter terminals 4 are electrically connected to the circuit board 5.

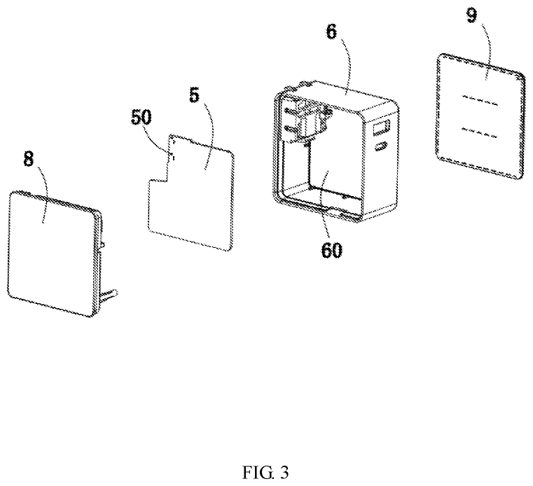

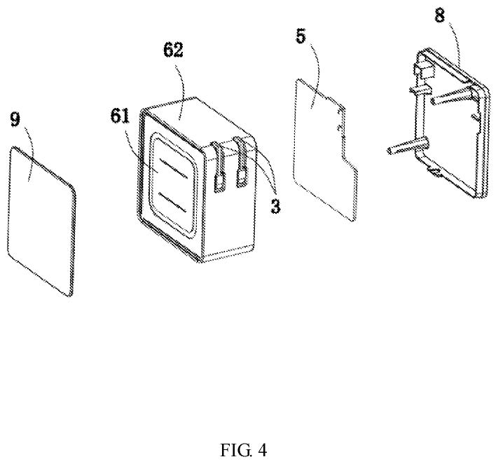

Referring to FIG. 3 and FIG. 4, the power plug of the present disclosure further includes a housing 6 which includes a bottom wall 61 and a side wall 62. The bottom wall 61 and the side wall 62 are enclosed to form a receiving space 60. The side wall 62 includes a buckle portion 621 extending toward the receiving space 60. The insulating body 1 is provided with a convex portion 11. The buckle portion 621 mates with the convex portion 11 to fix the insulating body 1 on the housing 6. That is, the terminal module of the present disclosure is assembled to the housing 6 as a whole, and is stably positioned through the mating of the buckle portion 621 and the convex portion 11.

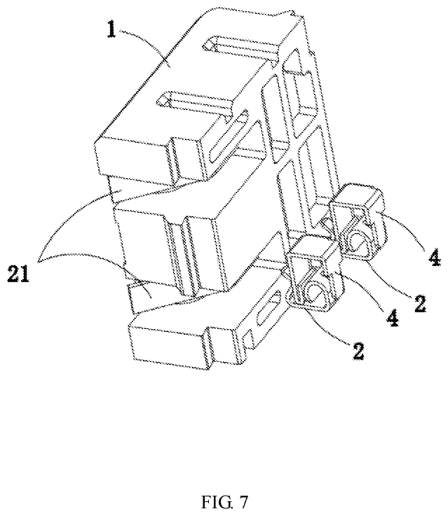

Referring to FIG. 7 to FIG. 9, the contact portion 22 includes a first contact arm 221, a second contact arm 222, and a connecting arm 223 connected between the first contact arm 221 and the second contact arm 222. The first contact arm 221, the connecting arm 223 and the second contact arm 222 form a U-shaped receiving cavity 220. The adapter terminal 4 has a base portion 41, a mating portion 42 extending downwardly from the base portion 41, and a retaining portion 43 extending downwardly from the base portion 41 in a same direction as the mating portion 42. The mating portion 42 is inserted into the receiving cavity 220 and is in constant contact with the contact portion 22.

Referring to FIG. 7 to FIG. 9, furthermore, the mating portion 42 includes a third contact arm 421 which is bent and extended from the base portion 41, and a fourth contact arm 422 which is reversely bent from an end of the third contact arm 421 and is parallel to the third contact arm 421. The first contact arm 221 and the third contact arm 421 are mated together. The second contact arm 222 and the fourth contact arm 422 are mated together.

Referring to FIG. 7 to FIG. 9, furthermore, the circuit board 5 is provided with a conductive hole 50. The retaining portion 43 is inserted into the conductive hole 50.

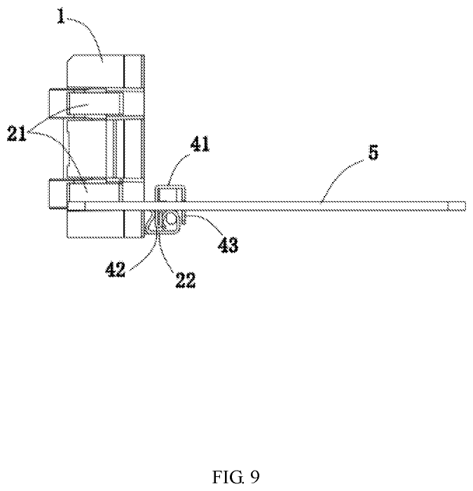

Referring to FIG. 9, the contact portion 22 is located below the circuit board 5. The base portion 41 is located above the circuit board 5. That is, the contact portion 22 and the base portion 41 are disposed on an upper side and a lower side of the circuit board 5, respectively.

Please continue to refer to FIG. 7 to FIG. 9, in the specific embodiment of the present disclosure, the number of the contact terminals 2 is two. Therefore, the two contact terminals 2 have two tail portions 21 and two contact portions 22. The arrangement of the contact terminals 2 is as follows: the two tail portions 21 are arranged side by side in a first plane; and the two contact portions 22 are arranged side by side in a second plane which is orthogonal to the first plane.

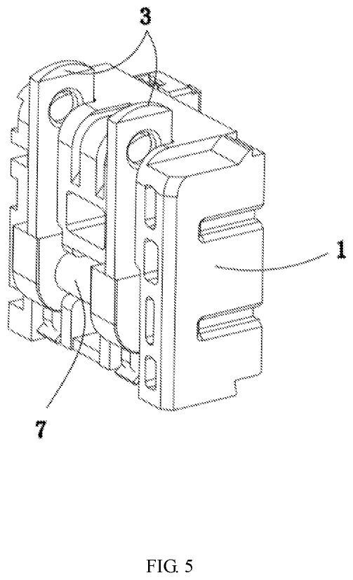

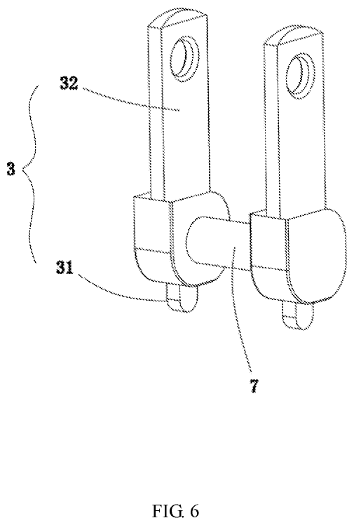

Referring to FIG. 5 and FIG. 6, the power plug of the present disclosure further includes a rotating shaft 7 pivotally connecting the pins 3 to the insulating body 1. The pin 3 has a first end 31 and a second end 32 which extend oppositely from the rotating shaft 7. The pins 3 are rotatable around the rotating shaft 7 so that the first end 31 and the tail portion 21 can be detachably contacted. That is, in the specific embodiment of the power plug of the present disclosure, the specific implementation of connecting the pins 3 to the insulating body 1 is to pivot through the rotating shaft 7. In other embodiments, the connection may also be achieved in other ways. For example, a groove is provided on the pin 3, and a convex hull is provided on the insulating body 1 that is mated with the groove.

Referring to FIG. 1 to FIG. 6, the side wall 62 is provided with an opening 620 communicating with the receiving space 60. The second end 32 can be embedded or protruded from the opening 620 as the pin 3 rotates. The opening 620 on the side wall 62 is used to receive the second end 32 of the pin 3, that is, to hide the pin 3 when not in use.

Referring to FIG. 3 and FIG. 4, an upper cover 8 for closing the receiving space 60 is installed above the housing 6. A lower cover 9 is attached and installed below the bottom wall 61 of the housing 6. The upper cover 8 and the lower cover 9 play the role of shielding, protecting and dustproof

The contact terminals 2 of the power plug of the present disclosure are insert-molded with the insulating body 1. That is, the contact terminals 2 and the insulating body 1 are integrally formed into the terminal module, and the terminal module can be assembled into the housing 6 as a whole. The power plug of the present disclosure is more stable in use, and is easy to assemble and replace after being damaged, thereby having the advantages of low cost, high strength, high safety, and simple assembly etc.

The above embodiments are only used to illustrate the present disclosure rather than limit the technical solutions described in the present disclosure. The understanding of this specification should be based on those skilled in the art. For example, for the description of “front”, “rear”, “left”, “right”, “top”, “bottom” and other directions, although this specification has described the present disclosure in detail with reference to the above-mentioned embodiments, but those skilled in the art should understand that those of ordinary skill in the art can still make modifications or equivalent replacements to the present disclosure. And all technical solutions and improvements that do not depart from the spirit and scope of the present disclosure should be included within the scope of the claims of the present disclosure.

1. A power plug, comprising: a conductive module, a pin, an adapter terminal and a circuit board, the conductive module comprising an injection-molded insulating body and a contact terminal secured to the insulating body during an injection molding process, the contact terminal comprising a tail portion which extends beyond the insulating body from one side of the insulating body and is configured to be connected to the pin, and a contact portion which extends beyond the insulating body from another side of the insulating body and is configured to mate with the adapter terminal, the adapter terminal being electrically connected with the circuit board.

2. The power plug according to claim 1, further comprising a housing which comprises a bottom wall and a side wall, the bottom wall and the side wall being enclosed to form a receiving space, the side wall comprising a buckle portion extending toward the receiving space, the insulating body being provided with a convex portion, the buckle portion mating with the convex portion to hold and position the insulating body on the housing.

3. The power plug according to claim 2, wherein the contact portion comprises a first contact arm, a second contact arm, and a connecting arm connected between the first contact arm and the second contact arm; the first contact arm, the connecting arm and the second contact arm form a U-shaped receiving cavity; the adapter terminal comprises a base portion, a mating portion extending downwardly from the base portion, and a retaining portion extending downwardly from the base portion in a same direction as the mating portion; and the mating portion is inserted into the receiving cavity and is in constant contact with the contact portion.

4. The power plug according to claim 3, wherein the mating portion comprises a third contact arm which is bent and extended from the base portion, and a fourth contact arm which is reversely bent from an end of the third contact arm and is parallel to the third contact arm; the first contact arm and the third contact arm are mated; and the second contact arm and the fourth contact arm are mated.

5. The power plug according to claim 3, wherein the circuit board is provided with a conductive hole, and the retaining portion is inserted into the conductive hole.

6. The power plug according to claim 3, wherein the contact portion is located below the circuit board, and the base portion is located above the circuit board.

7. The power plug according to claim 3, wherein the number of the contact terminals is two, the two contact terminals have two tail portions and two contact portions, the two tail portions are disposed side by side in a first plane, and the two contact portions are disposed side by side in a second plane which is orthogonal to the first plane.

8. The power plug according to claim 2, further comprising a rotating shaft pivotally connecting the pin to the insulating body, the pin comprising a first end and a second end which extend oppositely from the rotating shaft, the pin being rotatable around the rotating shaft so that the first end and the tail portion are detachably contacted.

9. The power plug according to claim 8, wherein the side wall is provided with an opening communicating with the receiving space, the second end being capable of being embedded or protruded from the opening with rotation of the pin.

10. The power plug according to claim 9, wherein an upper cover for closing the receiving space is installed above the housing, and a lower cover is attached and installed below the bottom wall of the housing.
